(19) United States
(12) Patent Application Publication
(10) Pub. No.: US 2020/0075438 A1
(43) Pub. Date: Mar. 5, 2020

(54) PACKAGING STRUCTURE

(71) Applicant: BOE Technology Group Co., Ltd., Beijing (CN)

(72) Inventors: Chengyuan LUO, Beijing (CN); Yongqi SHEN, Beijing (CN)

(21) Appl. No.: 16/426,792

(22) Filed: May 30, 2019

(30) Foreign Application Priority Data
Sep. 4, 2018 (CN) 201811024608.2

(51) Int. Cl. H01L 23/10; H01L 23/31; H01L 51/52

(52) U.S. Cl. CPC H01L 23/10; H01L 51/5246; H01L 23/3121

(57) ABSTRACT

A packaging structure is provided. The packaging structure includes a substrate and a packaging cover plate which are disposed opposite to each other. The substrate includes a first limiting member arranged at one side of the substrate close to the packaging cover plate. The packaging cover plate includes a second limiting member arranged at one side of the packaging cover plate close to the substrate, and the first limiting member and the second limiting member are engaged with each other to fix the substrate and the packaging cover plate.

### CROSS-REFERENCE TO RELATED APPLICATION

This application claims a priority to Chinese Patent Application No. 201811024608.2 filed on Sep. 4, 2018, the disclosure of which is incorporated by reference in its entirety herein.

### TECHNICAL FIELD

The present disclosure relates to the field of technologies for manufacturing display products, in particular to a packaging structure.

### BACKGROUND

As a display lighting technology, an organic light-emitting diode (OLED) has been developed gradually in recent years. In the display industry, due to its characteristics such as a high response, high contrast and flexibility, the OLED has a wide application prospect.

### SUMMARY

A packaging structure includes a substrate and a packaging cover plate which are disposed opposite to each other, where the substrate comprises a first limiting member arranged at one side of the substrate close to the packaging cover plate, the packaging cover plate comprises a second limiting member arranged at one side of the packaging cover plate close to the substrate, and the first limiting member and the second limiting member are engaged with each other to fix the substrate and the packaging cover plate.

In some embodiments of the present disclosure, the packaging structure further includes a first sealant layer arranged between the substrate and the packaging cover plate, where the first sealant layer is arranged on peripheries of the substrate and the packaging cover plate; the substrate, the packaging cover plate and the first sealant layer form a sealed space; and the first limiting member and the second limiting member are located outside the sealed space.

In some embodiments of the present disclosure, a height of the first limiting member in a direction perpendicular to the substrate is smaller than or equal to a height of the sealed space in the direction perpendicular to the substrate; and

a height of the second limiting member in the direction perpendicular to the substrate is smaller than or equal to a height of the sealed space in the direction perpendicular to the substrate.

In some embodiments of the present disclosure, the packaging structure further includes a second sealant layer with which the sealed space is filled.

In some embodiments of the present disclosure, the first sealant layer and the second sealant layer are each an ultraviolet-curable resin adhesive or thermosetting resin adhesive.

In some embodiments of the present disclosure, a gap is formed between an orthographic projection of the first limiting member on the packaging cover plate and an orthographic projection of the second limiting member on the packaging cover plate.

In some embodiments of the present disclosure, the gap ranges from 1 μm to 10 μm.

In some embodiments of the present disclosure, the first limiting member includes at least one cylindrical structure, and the second limiting member includes a frame structure with a limiting space surrounding the at least one columnar structure.

In some embodiments of the present disclosure, the second limiting member includes the frame structure formed by encircling at least three sides, and the at least one columnar structure is arranged at a corner of the frame structure.

In some embodiments of the present disclosure, the frame structure includes at least one opening communicated with the limiting space.

In some embodiments of the present disclosure, at least one opening is arranged between two adjacent sides of the at least three sides of the frame structure.

In some embodiments of the present disclosure, the second limiting member further comprises a plurality of limiting strips located within the frame structure, an extending direction of each of the plurality of limiting strips and one corresponding side of the at least three sides of the frame structure intersect, and two adjacent limiting strips of the plurality of limiting strips and one corresponding side of the at least three sides of the frame structure are encircled to form a limiting sub-space restricting the at least one columnar structure.

In some embodiments of the present disclosure, one end of each of the plurality of limiting strips is connected onto one corresponding side of the at least three sides of the frame structure, a gap is formed between two limiting strips of the plurality of limiting strips, and the two limiting strips are connected with one side of the at least three sides and another side of the at least three sides respectively, and the side and the another side are opposite to each other.

In some embodiments of the present disclosure, the at least one opening is arranged in the middle of each of the at least three sides of the frame structure.

In some embodiments of the present disclosure, the second limiting member further comprises a plurality of limiting strips located within the frame structure, an extending direction of each of the plurality of limiting strips and one corresponding side of the at least three sides of the frame structure intersect, and two adjacent limiting strips of the plurality of limiting strips and one corresponding side of the at least three sides of the frame structure are encircled to form a limiting sub-space restricting the at least one columnar structure.

In some embodiments of the present disclosure, each of the plurality of limiting strips comprises a first end and a second end which are disposed opposite to each other, wherein the first end is over against one corresponding opening of the at least one opening, the first end and the corresponding opening are separated by a preset distance, and the second end and other limiting strips of the plurality of limiting strips intersect.

In some embodiments of the present disclosure, the packaging structure further includes a lubricant arranged within the frame structure.

### BRIEF DESCRIPTION OF THE DRAWINGS

FIG. 1 is a schematic diagram showing a state where a substrate and a packaging cover plate of a packaging structure are not aligned with each other according to some embodiments of the present disclosure;

FIG. 2 is a schematic diagram showing a state where a first limiting member partially connects with a second limiting member of the packaging structure in FIG. 1;

FIG. 3 is a schematic diagram showing a state where the substrate and the packaging cover plate of the packaging structure of FIG. 1 are in an alignment;

FIG. 4 is a structural schematic diagram of the first limiting member and the second limiting member according to some embodiments of the present disclosure;

FIG. 5 is a structural schematic diagram of the first limiting member and the second limiting member according to some other embodiments of the present disclosure;

FIG. 6 is a structural schematic diagram of the first limiting member and the second limiting member according to some other embodiments of the present disclosure; and

FIG. 7 is a structural schematic diagram of the first limiting member and the second limiting member according to some other embodiments of the present disclosure.

### DETAILED DESCRIPTION

The technical solutions in the embodiments of the present disclosure will be clearly and completely described hereinafter with reference to the drawings. These embodiments described herein are merely parts of the embodiments of the present disclosure rather than all the embodiments. Based on the embodiments of the present disclosure, a person skilled in the art may obtain other embodiments.

Due to moisture and oxygen, an OLED device tends to be corroded and damaged. Therefore, the OLED device may be prevented from being corroded if packaged appropriately.

The OLED device may be packaged in a manner of film adhesive packaging, Frit packaging and Dam&Fill packaging. In the Dam&Fill packaging, both Dam and filler are used to package the device. Due to better watertightness, better oxidation resistance and a simpler structure than other packaging methods, the Dam&Fill packaging may be applied to package large-sized devices. Therefore, the Dam&Fill packaging is highly appreciated.

During a process of packaging the OLED device, an upper carrier pick up a substrate by suction, and a lower carrier carries a packaging cover plate which is gelatinized. After the substrate is aligned with the packaging cover plate according to a mark, the upper carrier releases the substrate which falls on and attaches with the packaging cover plate, and packaging is finished.

During the process of releasing the substrate, the substrate deviates from an alignment position with the packaging cover plate by more than dozens of micrometers due to a vibration of carriers and a turbulent flow of residual gas inside a cavity formed by the substrate and the packaging cover plate, which reduces an alignment accuracy of the substrate with the packaging cover plate.

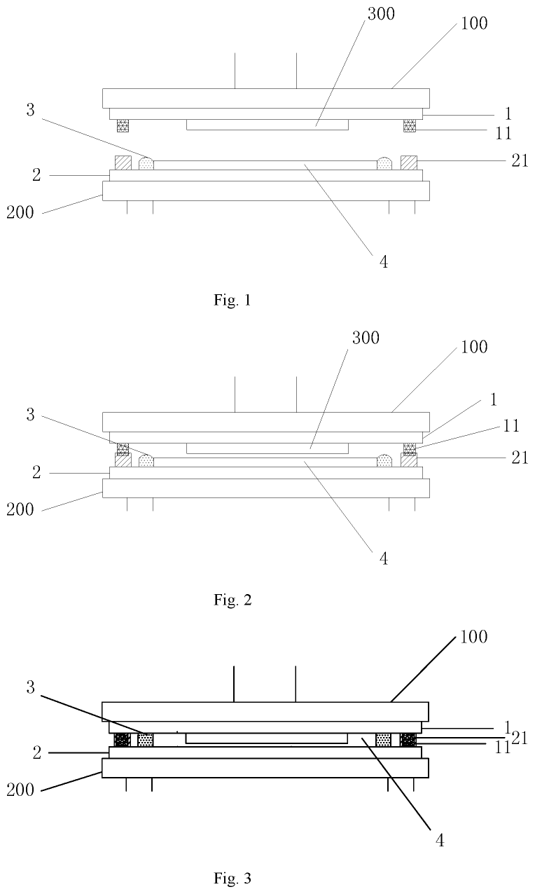

In some embodiments of the present disclosure, there is provided a packaging structure, as shown in FIG. 1, including a substrate 1 and a packaging cover plate 2 which are disposed opposite to each other.

The substrate 1 includes a first limiting member 11 arranged at one side of the substrate 1 close to the packaging cover plate 2.

The packaging cover plate 2 includes a second limiting member 21 arranged at one side of the packaging cover plate 2 close to the substrate 1. The first and second limiting member 11 and 21 are engaged with each other to fix the substrate 1 and the packaging cover plate 2. That is, in the process of aligning the substrate 1 with the packaging cover plate 2, the substrate 1 with the packaging cover plate 2 are fixed through the first limiting member 11 and the second limiting member and 21.

The packaging structure according to the above embodiments avoids deviation generated when the substrate and the packaging cover plate are aligned together.

FIG. 1 is a schematic diagram showing a state where the substrate 1 and the packaging cover plate 2 are aligned with each other; FIG. 2 is a schematic diagram showing a state where the first limiting member 11 partially connects with the second limiting member 21; and FIG. 3 is a schematic diagram showing a state where the substrate 11 and the packaging cover plate 21 are in an alignment. The substrate 1 and the packaging cover plate 2 are laminated through the first limiting member 11 and the second limiting member 21, which guarantees the alignment accuracy.

In some embodiments of the present disclosure, the first limiting member 11 is arranged on different positions on the substrate 1 and position of the second limiting member 21 is corresponds with the position of the first limiting member 11.

In some embodiments of the present disclosure, the number of the first limiting member 11 is one, two, three or more, and the number of the second limiting member 21 is the same as the number of the first limiting member 11.

In some embodiments of the present disclosure, the packaging structure further includes a first sealant layer 3 arranged between the substrate 1 and the packaging cover plate 2, the first sealant layer 3 is arranged on peripheries of the substrate 1 and the packaging cover plate 2, the substrate 1, the packaging cover plate 2 and the first sealant layer 3 form a sealed space, and both the first limiting member 11 and second limiting member 21 are located outside the sealed space.

The arrangement of the first sealant layer 3 prevents the first limiting member 11 and second limiting member 21 from affecting the packaging effects of the device to be packaged.

In some embodiments of the present disclosure, a height of the first limiting member 11 in a direction perpendicular to the substrate 1 is smaller than or equal to a height of the sealed space in the direction perpendicular to the substrate 1, and a height of the second limiting member 21 in the direction perpendicular to the substrate 1 is smaller than or equal to a height of the sealed space in the direction perpendicular to the substrate 1.

In some embodiments of the present disclosure, a height of the first limiting member 11 in a direction perpendicular to the substrate 1 is smaller than a height of the sealed space in the direction perpendicular to the substrate 1, and a height of the second limiting member 21 in the direction perpendicular to the substrate 1 is smaller than a height of the sealed space in the direction perpendicular to the substrate 1.

The setting of heights of the first limiting member 11 and second limiting member 21 avoid the substrate 1 and the packaging cover plate 2 pressing against at least one of the first limiting member 11 and second limiting member 21 after the substrate 1 and the packaging cover plate 2 are laminated in an alignment, avoid a deformation of at least one of the first limiting member 11 and second limiting member 21, and ensure that at least one of first limiting member 11 and second limiting member 21 assists the substrate 1 and the packaging cover plate 2.

In some embodiments of the present disclosure, there is a gap between an orthographic projection of the first limiting member 11 on the packaging cover plate 2 and an orthographic projection of the second limiting member 21 on the packaging cover plate 2.

The gap between the orthographic projection of the first limiting member 11 on the packaging cover plate 2 and the orthographic projection of the second limiting member 21 on the packaging cover plate 2 is greater than or equal to a maximum alignment error between the substrate 1 and the packaging cover plate 2, which ensures that the first limiting member 11 and second limiting member 21 are engaged with each other to fix the positions of the substrate 1 and the packaging cover plate 2.

In some embodiments of the present disclosure, the gap between the orthographic projection of the first limiting member 11 on the packaging cover plate 2 and the orthographic projection of the second limiting member 21 on the packaging cover plate 2 is configured to fill with a lubricant.

In some embodiments of the present disclosure, the gap between the orthographic projection of the first limiting member 11 on the packaging cover plate 2 and the orthographic projection of the second limiting member 21 on the packaging cover plate 2 ranges from 1 μm to 10 μm.

The gap between the orthographic projection of the first limiting member 11 on the packaging cover plate 2 and the orthographic projection of the second limiting member 21 on the packaging cover plate 2 is controlled to range from 1 μm and 10 μm. While the maximum alignment error between the substrate 1 and the packaging cover plate 2 is smaller than or equal to the gap, a movement error after the substrate 1 and the packaging cover plate 2 are aligned with each other is in a small range, ensuring the alignment accuracy of the substrate 1 with the packaging cover plate 2.

The first limiting member 11 and second limiting member 21 have a plurality of structures. The first limiting member 11 and second limiting member 21 are engaged with each other to fix the substrate 1 and the packaging cover plate 2.

In some embodiments of the present disclosure, the first limiting member 11 includes at least one columnar structure, and the second limiting member 21 includes a frame structure with a limiting space surrounding the at least one columnar structure.

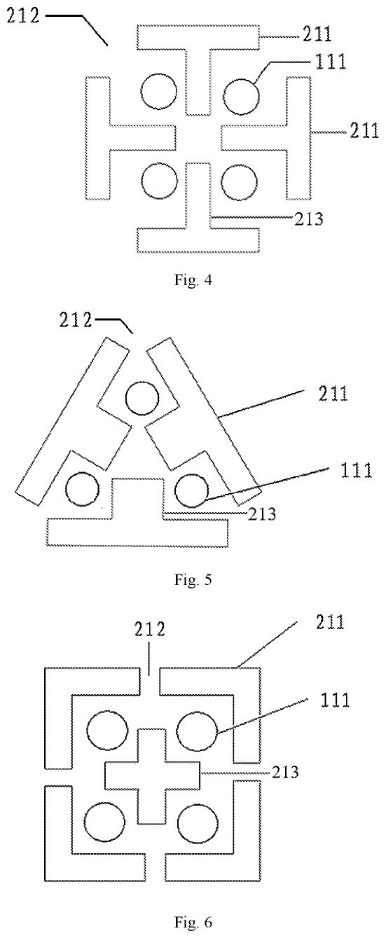

For example, as shown in FIG. 4, one first limiting member 11 includes four columnar structures 111, and the second limiting member 21 which is engaged with the first limiting member 11 includes a frame structure with a limiting space surrounding the four columnar structures 111.

For another example, as shown in FIG. 5, one first limiting member 11 includes three columnar structures 111, and the second limiting member 21 which is engaged with the first limiting member 11 includes a frame structure with a limiting space surrounding the three columnar structures 111.

In some embodiments of the present disclosure, the at least one columnar structure is a cylindrical structure having an end diameter ranging from 20 μm to 100 μm.

In some embodiments of the present disclosure, one first limiting member 11 includes one, two, three, four or more columnar structures.

In some embodiments of the present disclosure, the frame structure has a shape of a regular rectangle or circle.

In some embodiments of the present disclosure, the frame structure has an irregular shape.

In some embodiments of the present disclosure, one columnar structure is arranged within one limiting space.

In some embodiments of the present disclosure, two or more columnar structures are arranged within one limiting space.

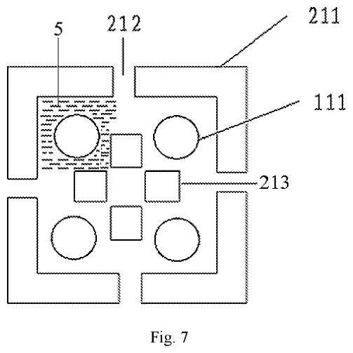

For example, in FIGS. 4 and 6, four columnar structures 111 are arranged in one limiting space. For another example, in FIG. 5, three columnar structures 111 are arranged in one limiting space.

In some embodiments of the present disclosure, the second limiting member 21 includes the frame structure formed by encircling at least three sides 211, and the at least one columnar structure is arranged at a corner of the frame structure.

When the substrate 1 and the packaging cover plate 2 are laminated in an alignment, the columnar structure is inserted into a corner of the frame structure, fixing the substrate 1 and the packaging cover plate 2.

In some embodiments of the present disclosure, the frame structure has a frame 211 with a length ranging from 0.5 mm to 1 mm.

In some embodiments of the present disclosure, the frame structure includes at least one opening 212 communicated with the limiting space.

This opening 212 has a function of releasing a stress.

The first limiting member 11 and second limiting member 21 are made of many kinds of materials and formed by many kinds of processes.

In some embodiments of the present disclosure, the first limiting member 11 and second limiting member 21 are both made of resin photoresist.

In some embodiments of the present disclosure, a structure with a height ranging from 5 μm to 15 μm is formed by coating and photoetching, as the first limiting member 11 and second limiting member 21.

The opening included in the frame structure also functions to discharge redundant adhesive.

The position of the opening is set as needed.

In some embodiments of the present disclosure, the opening is arranged between two adjacent sides of the frame structure, or the opening is arranged in the middle of each side of the frame structure.

As shown in FIGS. 4 and 5, the opening 212 is arranged between two adjacent sides 211 of the frame structure. As shown in FIG. 6, the opening 212 is arranged in the middle of each side 211 of the frame structure.

In some embodiments of the present disclosure, the second limiting member 21 further includes a plurality of limiting strips 213 located within the frame structure. An extending direction of each of the plurality of limiting strips 213 and one corresponding side of the at least three sides 211 of the frame structure intersect, and the two adjacent limiting strips 213 of the plurality of limiting strips and one corresponding side of the at least three sides 211 of the frame structure are encircled to form a limiting sub-space restricting the at least one columnar structure.

The plurality of limiting strips 213 enhances the fixing effect.

As shown in FIGS. 4 and 5, the substrate 1 and the packaging cover plate 2 are aligned each other, and one columnar structure 111 is set within one limiting sub-space, which increases the alignment accuracy of the substrate 1 with the packaging cover plate 2.

The limiting strips have many kinds of set positions and structures.

In some embodiments of the present embodiments, the opening is arranged between two adjacent sides of the frame structure, one end of the limiting strip is connected onto the side of the frame structure, a gap is formed between two limiting strips of the plurality of limiting strips, and the two limiting strips are connected with one side of the at least three sides and another side of the at least three sides respectively, and the side and the another side are opposite to each other.

As shown in FIGS. 4 and 5, the frame structure in FIG. 4 consists of four sides 211, and the frame structure in FIG. 5 consists of three sides 211. As shown in FIG. 4, the opening 212 is arranged between two adjacent sides 211 of the frame structure, one end of the limiting strip 213 is connected onto the side 211 of the frame structure, a gap is formed between two limiting strips of the plurality of limiting strips 213, and the two limiting strips 213 are connected with one side of the at least three sides 211 and another side of the at least three sides 211 respectively, and the side and the another side are opposite to each other.

In some embodiments of the present disclosure, as shown in FIG. 6, the opening 212 is arranged in the middle of each side 211 of the frame structure, the limiting strip 213 includes a first end and a second end which are disposed opposite to each other, the first end is over against the corresponding opening 212, the first end and the corresponding opening 212 are separated by a preset distance, and the second end and other limiting strips of the plurality of limiting strips intersect.

In some other embodiments of the present disclosure, as shown in FIG. 7, there is a gap between the second end of the limiting strip and other limiting strips.

In some embodiments of the present disclosure, the packaging structure further includes a second sealant layer 4 with which the sealed space is filled.

The substrate 1, the packaging cover plate 2 and the first sealant layer 3 form a sealed space, and a filling adhesive is arranged on a side of the packaging cover plate 2 close to the substrate 1 to fill the sealed space and form the second sealant layer 4. In a process of packaging a device 300 to be packaged, the second sealant layer 4 is set on a periphery of the device 300 to be packaged. As shown in FIGS. 1-3, the second sealant layer 4 ensures the packaging performance.

In some embodiments of the present disclosure, the first sealant layer 3 and the second sealant layer 4 are each an ultraviolet-curable resin adhesive or thermosetting resin adhesive.

The each an ultraviolet-curable resin adhesive or thermosetting resin adhesive has hydrophobicity.

In some embodiments of the present disclosure, the first sealant layer 3 and the second sealant layer 4 are made of at least one of the following materials: homopolymer or copolymer of a monomer such as epoxy resin, glycidyl acrylate, glycidyl methacrylate, methyl methacrylate, ethyl methacrylate, n-butyl methacrylate, poly(methylacrylic acid 6, 7-epoxy heptyl ester), and 2-hydroxyethyl methacrylate.

In some embodiments of the present disclosure, the first sealant layer 3 and the second sealant layer 4 are made of at least one of the following materials: melamine formaldehyde resin and unsaturated polyester resin.

In some embodiments of the present disclosure, the packaging structure further includes a lubricant 5 arranged within the frame structure.

In order to facilitate the connecting the columnar structure and the frame structure, the lubricant 5 is arranged within the frame structure, which prevents an overlarge friction between the first limiting member 11 and the second limiting member 21, so that the substrate 1 and the packaging cover plate 2 fail to be aligned, and the substrate 1 or the packaging cover plate 2 is warping locally.

In some embodiments of the present disclosure, a process of packaging a device 300 to be packaged includes:

arranging the first limiting member 11 on the substrate 1;

arranging the second limiting member 21 on a packaging cover plate 2, and the second limiting member 21 and the first limiting member 11 are coupled to fix the substrate 1 and the packaging cover plate 2;

coating the first sealant layer 3 and the second sealant layer 4 on the packaging cover plate 2, and coating a small amount of filling adhesive (that is the lubricant 5 which is for example, made of the same material as the first sealant layer 3 and the second sealant layer 4) in the second limiting member 21;

picking up the substrate 1 by suction through the first carrier 100, carrying the packaging cover plate 2 by the second carrier 200, moving the first carrier 100 horizontally to align the substrate 1 with the packaging cover plate 2. The first carrier 100 is moved in a direction close to the second carrier after the substrate 1 is aligned with the packaging cover plate 2, such that the first limiting member 11 and second limiting member 21 are coupled. As shown in FIG. 2, the columnar structure is within the limiting space of the second limiting member 21 partially, the first carrier 100 releases the substrate 1, and lamination of the substrate 1 and the packaging cover plate 2 is finished through the first limiting member 11 and second limiting member 21, thereby ensuring the alignment accuracy of the substrate 1 with the packaging cover plate 2.

The above descriptions are merely some embodiments of the present disclosure. Several improvements and modifications may be made for a person skilled in the art without departing from the principle of the present disclosure.

What is claimed is:

1. A packaging structure, comprising a substrate and a packaging cover plate which are disposed opposite to each other,
wherein the substrate comprises a first limiting member arranged at one side of the substrate close to the packaging cover plate;
the packaging cover plate comprises a second limiting member arranged at one side of the packaging cover plate close to the substrate, and the first limiting member and the second limiting member are engaged with each other to fix the substrate and the packaging cover plate.

2. The packaging structure according to claim 1, further comprising a first sealant layer arranged between the substrate and the packaging cover plate,
wherein the first sealant layer is arranged on peripheries of the substrate and the packaging cover plate; the substrate, the packaging cover plate and the first sealant layer form a sealed space; and the first limiting member and the second limiting member are located outside the sealed space.

3. The packaging structure according to claim 2, wherein a height of the first limiting member in a direction perpendicular to the substrate is smaller than or equal to a height of the sealed space in the direction perpendicular to the substrate; and
a height of the second limiting member in the direction perpendicular to the substrate is smaller than or equal to a height of the sealed space in the direction perpendicular to the substrate.

4. The packaging structure according to claim 2, further comprising a second sealant layer, with which the sealed space is filled.

5. The packaging structure according to claim 4, wherein the first sealant layer and the second sealant layer are each an ultraviolet-curable resin adhesive or thermosetting resin adhesive.

6. The packaging structure according to claim 1, wherein a gap is formed between an orthographic projection of the first limiting member on the packaging cover plate and an orthographic projection of the second limiting member on the packaging cover plate.

7. The packaging structure according to claim 6, wherein the gap ranges from 1 μm to 10 μm.

8. The packaging structure according to claim 1, wherein the first limiting member comprises at least one columnar structure, and the second limiting member comprises a frame structure with a limiting space surrounding the at least one columnar structure.

9. The packaging structure according to claim 8, wherein the second limiting member comprises the frame structure formed by encircling at least three sides, and the at least one columnar structure is arranged at a corner of the frame structure.

10. The packaging structure according to claim 9, wherein the frame structure comprises at least one opening communicated with the limiting space.

11. The packaging structure according to claim 10, wherein the at least one opening is arranged between two adjacent sides of the at least three sides of the frame structure.

12. The packaging structure according to claim 11, wherein the second limiting member further comprises a plurality of limiting strips located within the frame structure, an extending direction of each of the plurality of limiting strips and one corresponding side of the at least three sides of the frame structure intersect, and two adjacent limiting strips of the plurality of limiting strips and one corresponding side of the at least three sides of the frame structure are encircled to form a limiting sub-space restricting the at least one columnar structure.

13. The packaging structure according to claim 12, wherein one end of each of the plurality of limiting strips is connected onto one corresponding side of the at least three sides of the frame structure, a gap is formed between two limiting strips of the plurality of limiting strips, and the two limiting strips are connected with one side of the at least three sides and another side of the at least three sides respectively, and the side and the another side are opposite to each other.

14. The packaging structure according to claim 10, wherein the at least one opening is arranged in the middle of each of the at least three sides of the frame structure.

15. The packaging structure according to claim 14, wherein the second limiting member further comprises a plurality of limiting strips located within the frame structure, an extending direction of each of the plurality of limiting strips and one corresponding side of the at least three sides of the frame structure intersect, and two adjacent limiting strips of the plurality of limiting strips and one corresponding side of the at least three sides of the frame structure are encircled to form a limiting sub-space restricting the at least one columnar structure.

16. The packaging structure according to claim 15, wherein each of the plurality of limiting strips comprises a first end and a second end which are disposed opposite to each other, wherein the first end is over against one corresponding opening of the at least one opening, the first end and the corresponding opening are separated by a preset distance, and the second end and other limiting strips of the plurality of limiting strips intersect.

17. The packaging structure according to claim 8, further comprising a lubricant arranged within the frame structure.
